(19) United States
(12) Patent Application Publication
(10) Pub. No.: US 2024/0244761 A1
(43) Pub. Date: Jul. 18, 2024

(54) PACKAGES WITH A SHORTEST DISTANCE BETWEEN PACKAGE CONNECTORS AND A SEATING PLANE OF AT LEAST 6 MILS

(71) Applicant: Microchip Technology Incorporated, Chandler, AZ (US)

(72) Inventors: Zhiyang Wang, Irvine, CA (US); Bianca Kwok, Walnut, CA (US); Benson Tu, Rosemead, CA (US); Adrian Ocampo, Anaheim, CA (US)

(73) Assignee: Microchip Technology Incorporated, Chandler, AZ (US)

(21) Appl. No.: 18/196,144

(22) Filed: May 11, 2023

Related U.S. Application Data
(60) Provisional application No. 63/439,794, filed on Jan. 18, 2023.

(51) Int. Cl. H05K 3/34; H05K 1/11

(52) U.S. Cl. CPC H05K 3/3436; H05K 1/111; H05K 3/3421; H05K 3/3485; H05K 2201/2036

(57) ABSTRACT

An integrated circuit package with a package connector and at least three bottom-most points of the package that define a seating plane, wherein the shortest distance between the seating plane and the package connector solder surface is at least 6 mils (0.152 mm). A printed circuit board comprising a pad; an integrated circuit package comprising a package connector and at least three bottom-most points of the package in contact with the printed circuit board; and a solder column having a height at least 6 mils (0.152 mm) electrically and mechanically connecting the pad to the package connector. Methods for controlling solder column height are disclosed.

The present application claims priority to U.S. Provisional Patent Application No. 63/439,794 filed Jan. 18, 2023, the contents of which are hereby incorporated in their entirety.

### TECHNICAL FIELD

The present disclosure relates to integrated circuit packaging of microchips for printed circuit boards, in particular, it relates to the electrical connection of package connectors to printed circuit boards via package connectors that do not extend below the seating planes of the packages.

### BACKGROUND

Thermal cycle induced fatigue is the lead failure factor for electronics under harsh environments: electric vehicles, aircrafts, and satellites. Traditionally this issue was handled by many technical constraints/workaround during design: printed circuit board construction to reduce its thermal growth rate (extremely expensive PCB: Copper-Invar-Copper); reducing temperature rise (conservative design, less than optimal electronic performance); complicated cooling setup (bulkier and higher cost); relocating larger integrated circuit chips away from hot spots (electrical layout complication, less optimal robustness and noise rejections); and avoid using IC packages without lead pin package connectors (e.g. avoiding Leadless Chip Carrier packages).

Because of a difference in thermal expansion, the solder connections fail by thermal fatigue. The component package may experience a small expansion and the PCB may experience a relatively larger expansion. Shear forces due to differences in thermal expansion between component packages and PCBs are induced in the solder. The shear forces induce stresses and strains inside the solder material. Cold/hot thermal cycles due to environment or device operating conditions give cyclic characteristics to the stresses and strains within the solder material. These cyclic stresses and stress induce cyclic fatigue of the solder material. Cyclic fatigue is particularly problematic where integrated circuit board packages are used in harsh thermal environments. The difference in thermal expansion causes the solder pad to lift, or solder column themselves to crack and/or break.

Integrated circuit (IC) packages of the prior art have package connectors or terminals, which are commonly called pins, pads, or leads, that extend below the bottom of the integrated circuit component package so that a gap exists between IC bottom and PCB when soldered, particularly for surface mount devices. The seating plane of the component package is generally defined by the lower-most points of the package connector pins, which rest upon pads of the PCB. Component packages have a gap between the IC bottom and the PCB where the seating plane is below the IC bottom. The standoff dimension is defined as the dimension between the seating plane and the IC bottom. Component packages have a positive standoff dimension.

Traditionally, when an extended solder column is desired in order to improve a thermal cycle life, a solder paste stencil is used to set-up solder paste columns on pads of a printed circuit board. The thickness of the solder paste stencil, traditionally about 5 mils (0.127 mm), defines the height of the solder paste column on each pad. Integrated circuit packages are then placed with their package connectors over the solder paste columns and the PCB, IC packages, and solder paste columns are heated until the solder paste columns melt and soften to allow the weight of the integrated circuit packages to press their package connectors into the solder paste columns, which leads to uneven solder column height between package connectors, and in particular, much shorter solder column height than what was defined by the solder paste stencil thickness, traditionally about 5 mils (0.127 mm).

Unfortunately, with a gap under IC bottom, solder height cannot be uniformly controlled such that there is variation of thermal cycle lives between production units, which is a quality issue. With a gap, solder height cannot be easily and precisely raised or adjusted to improve thermal cycle lives. A gap between the IC bottom and the PCB may reduce the effectiveness of a thermal cooling path for the IC, unless additional thermal conducting materials are added to bridge the gap.

Solder between package connector pins, pads, and leads on printed circuit boards, when an extended solder column is desired for control of thermal cycle life, has a traditional height of 5 mils (0.127 mm), however as indicated above this height is in practice not well controlled.

There is a need for hardware implementations of integrated circuit board packages that are resistant to failure by cyclic fatigue.

### SUMMARY

Aspects provide devices, systems and methods related to integrated circuit component packages with package connector solder surfaces, the IC bottom thereby defining the seating planes of the packages, wherein the shortest distance between the seating planes and the package connector solder surfaces is at least 6 mils (0.152 mm), 8 mils (0.203 mm), or 10 mils (0.254 mm) to impose solder column heights of at least 6 mils (0.152 mm), 8 mils (0.203 mm), or 10 mils (0.254 mm).

According to an aspect, there is provided an integrated circuit package comprising a package connector with a solder surface and at least three bottom-most points of the package that define a seating plane, wherein the shortest distance between the seating plane and the package connector solder surface is at least 6 mils (0.152 mm).

An aspect provides a system comprising: a printed circuit board comprising a pad; an integrated circuit package comprising a package connector and at least three bottom-most points of the package in contact with the printed circuit board; and a solder column having a height at least 6 mils (0.152 mm) electrically and mechanically connecting the pad to the package connector.

According to an aspect, there is provided a method comprising: forming an integrated circuit package comprising a package connector with a solder surface and at least three bottom-most points of the package that define a seating plane; positioning the integrated circuit package relative to a printed circuit board so that a shortest distance between a package connector solder surface of the integrated circuit package and a pad of the printed circuit board is at least 6 mils (0.152 mm); and soldering the package connector to the pad.

### BRIEF DESCRIPTION OF THE DRAWINGS

The figures illustrate examples of devices, systems and methods related to integrated circuit board packages with package connectors that do not extend below seating planes of the packages and have solder column heights that are thereby constrained to be uniformly at least 6 mils (0.152 mm), 8 mils (0.203 mm), or 10 mils (0.254 mm).

FIG. 1 shows a top view of a printed circuit board with solder columns on pads.

FIGS. 2A, 2B, and 2C show bottom perspective, bottom, and side views, respectively, of an integrated circuit package to impose solder column height via a shortest distance between a seating plane and package connectors.

FIG. 3 shows a side view of a package seated on a printed circuit board with solder columns connecting package connectors to pads.

FIGS. 4A and 4B show bottom and side views, respectively, of a package with a shortest distance between package connectors and a seating surface.

FIG. 5 shows a side view of a package seated on a printed circuit board with a standoff spacer between and solder columns connecting package connectors to pads of the printed circuit board.

FIG. 6A shows a package with a shortest distance between package connectors (leads) and a seating surface.

FIG. 6B shows a package with a shortest distance between package connectors (pins) and a seating surface.

FIG. 6C shows a package with a shortest distance between package connectors (pads) and a seating surface.

FIG. 6D shows a package with a shortest distance between a lowest solder surface of a package connector (lead) and a seating surface.

FIG. 7 shows a table of cycles to failure data for packages having different solder column height (solder thickness).

FIG. 8 shows a method for controlling solder column height.

FIGS. 9A-9D show cross-sectional, side views of a printed circuit board at sequential steps of a solder column forming process using a solder stencil.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

Aspects provide devices, systems, and methods related to integrated circuit board packages with package connectors and seating planes that constrain solder column heights to be uniformly at least 6 mils (0.152 mm), 8 mils (0.203 mm), or 10 mils (0.254 mm).

Aspects provided may be used for printed circuit board level implementation or to provide additional packaging options for integrated circuits for high reliability applications. Further aspects increase fatigue life of integrated circuit products with reduced design limitations and reduce variation of fatigue life and improve quality for integrated circuit products or products using integrated circuits.

According to an aspect, an integrated circuit package is configured to control solder height when mounted to a printed circuit board, and further to provide taller than traditional solder height, by configuring the package connectors to be at least 6 mils (0.152 mm) away from a package seating plane. A solder paste stencil may be used to set-up solder paste columns on pads of a printed circuit board. The thickness of the solder paste stencil, may be greater than about 6 mils (0.152 mm) to define the height of the solder paste column on each pad. An integrated circuit package may then be placed with its seating plane on a PCB seating surface so that the package connector solder surfaces are over the solder paste columns. The IC package, the PCB, and solder paste columns may be heated until the solder paste columns melt and soften to allow the package connector solder surfaces to solder with the solder paste columns. Because the seating plane of the IC package is seated on the seating surface of the PCB without a gap between, the weight of the IC package may not be able to press the package connectors into the molten solder to deform or shorten the solder paste columns, so that uniform solder columns at least 6 mils (0.152 mm) may be consistently achieved.

Hardware implementation improvements may be done to improve the thermal cycle fatigue life by adding additional solder column height above a traditional value. Traditional utensil dimensions may be increased to add additional solder column height. Additional gapping material may be added under the integrated circuit packages to raise and evenly/constantly/tightly control the solder column height under the package connectors. Integrated circuit packaging features may be added for highly reliable integrated circuit (HiRel IC) packaging to control chip installation at a taller height relative to the printed circuit board. Solder column height of at least 6 mils (0.152 mm), 8 mils (0.203 mm), or 10 mils (0.254 mm). may increase the fatigue life by allowing more thermal cycles and may reduce variation of cycles to failure and improve mass production quality.

The integrated circuit package may be any type of package and the package connectors may be any type. For example, the package may be a surface mount package, a chip carrier package, or a flat package having pad package connectors for connection with pads on a printed circuit board via solder balls or solder columns. The package may be a pin grid array package with pin package connectors. The package may be a ball grid array package with pad package connectors. Other packages and package connectors may also be used.

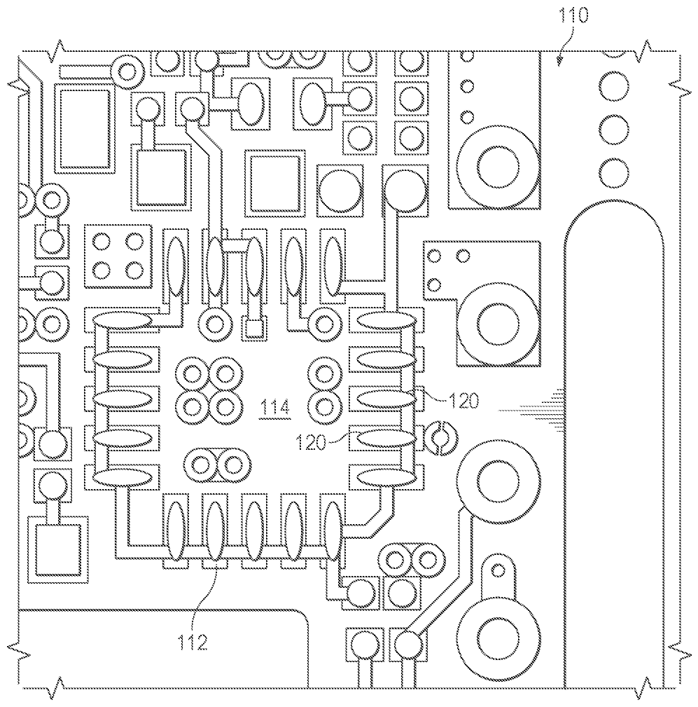

FIG. 1 shows a top view of a printed circuit board 110 with solder columns 120 on pads 112 of the printed circuit board 110. The pads 112 on the printed circuit board 110 are flush with the surface on which packages seat on the printed circuit board 110. The solder column height may be at least 6 mils (0.152 mm), 8 mils (0.203 mm), or 10 mils (0.254 mm). A seating surface 114 is provided for placement of a package on the printed circuit board 110.

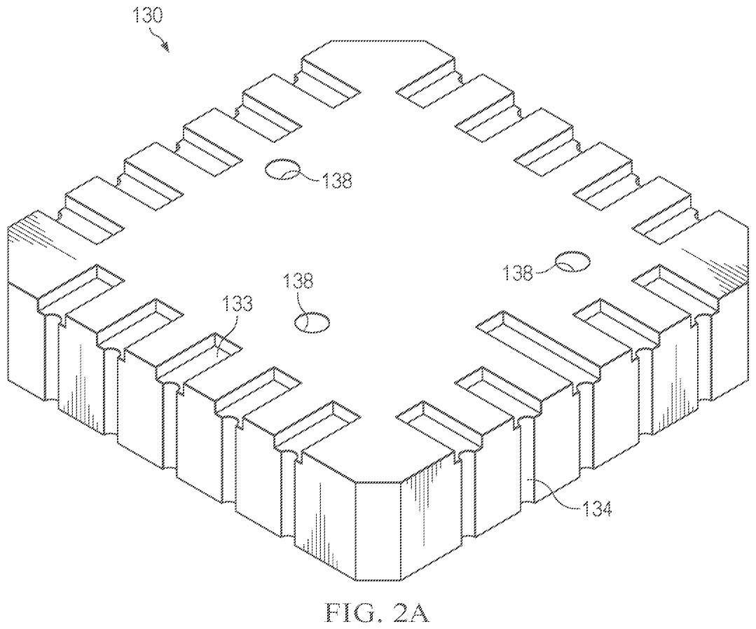

FIGS. 2A, 2B, and 2C show bottom perspective, bottom, and side views, respectively, of a package 130. The package 130 may be highly reliable because it has the ability to endure many thermal cycles to failure. The package 130 has a bottom 132 having at least three bottom-most points 148 that define a seating plane 144. Package connectors 134 are positioned in sides 136 above the seating plane 144. Each package connector 134 has a package connector solder surface 133 where a solder column (see FIG. 1) may solder to the package connector 134. FIG. 2A is a three dimensional perspective bottom view showing that the package connectors are recessed into the package. The shortest distance 146 is a distance between the lowest point of a package connector solder surface 133 and the seating plane 144. In one example, the lowest point of a package connector solder surface 133 defines a connector plane 135 parallel to a seating plane 144, with the shortest distance 146 being the distance between the planes. The package 130 may have a shortest distance 146 at least 6 mils (0.152 mm), 8 mils (0.203 mm), or 10 mils (0.254 mm).

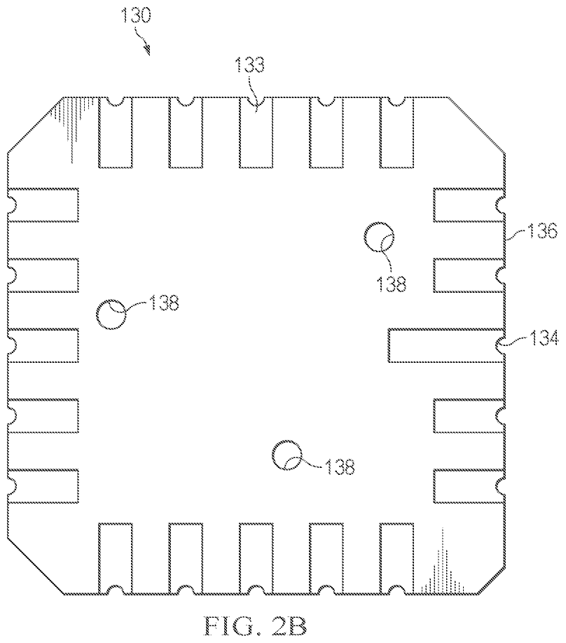

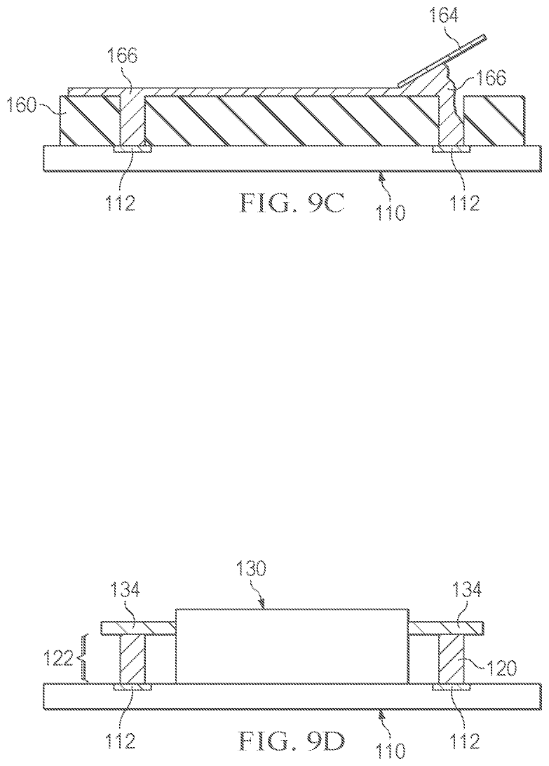

FIG. 3 shows a side view of a system having a printed circuit board and an integrated circuit package. The package 130 has a bottom 132 having at least three bottom-most points 138 (see FIGS. 2A and 2B) seated on a seating surface 114 of the printed circuit board 110. The package 130 has package connectors 134 extending from sides 136 thereof exhibiting respective package connector solder surfaces 133. The printed circuit board 110 has pads 112 flush with the upper surface of printed circuit 110. The shortest distance 146 is the distance between a package connector solder surface 133 and a corresponding pad 112. In one example, the lowest point of a package connector solder surface 133 defines a connector plane 135 parallel to a seating plane 144, with the shortest distance 146 being between the planes. A solder column 120 extends between respective package connector solder surfaces 133 of the respective package connectors 134 and corresponding pad 112. The height 122 of the solder column 120 is the same length as the shortest distance 146. The package 130 may have a shortest distance 146 at least 6 mils (0.152 mm), 8 mils (0.203 mm), or 10 mils (0.254 mm). The solder column 120 may be manually formed between the package connector solder surface 133 of the package connector 134 and a corresponding pad 112, or it may be formed via masking the PCB with a solder stencil. See FIGS. 9A-9D.

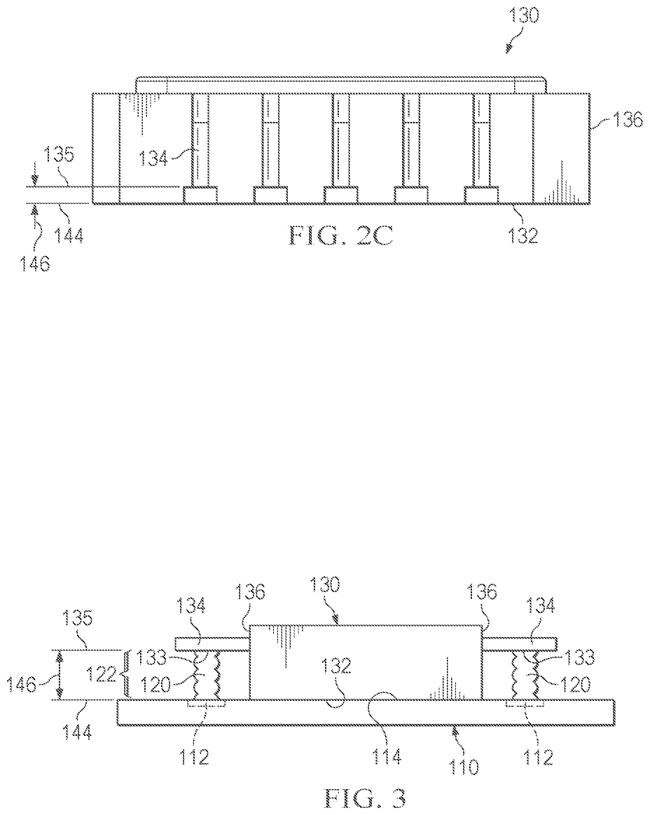

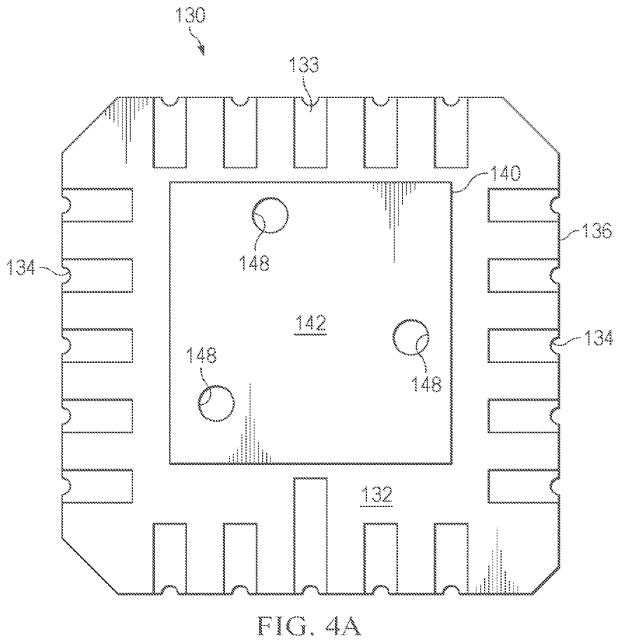

FIGS. 4A and 4B show top and side views, respectively, of a package 130 having a standoff spacer 140 to accommodate higher or taller solder columns. The illustrated package 130 is a leadless chip carrier (LCCC). The standoff spacer 140 may be attached to a bottom 132 of the package 130 before placing on a printed circuit board. With the standoff spacer 140 attached to the bottom 132 of the package 130, the standoff spacer 140 has a bottom 142 that defines a seating plane 144. A distance between the lowest point of a package connector 134 and the seating plane 144 is the shortest distance 146. In one example, the lowest point of a package connector 134, i.e. a package connector solder surface 133, defines a connector plane 135 parallel to a seating plane 144, with the shortest distance 146 being between the connector plane 135 and the seating plane 144. The bottom 142 of the standoff spacer 140 is arranged to make contact with, and seat on, a printed circuit board when the package connectors 134 are positioned over pads 112 of the printed circuit board 110. (See FIG. 1). As indicated above, a shortest distance 146 is between a package connector 134, i.e., between a package connector solder surface 133 of the package connector 134, and the package seating plane 144, which corresponds to solder column height 122. (See FIG. 5). A solder column 120 may connect a package connector 134 to a pad 112 of a printed circuit board 110 when solder column 120 is tall enough or has sufficient height to bridge the shortest distance 146 therebetween. To make a connection, the solder column height is at least equal to this shortest distance 146 between a package connector solder surface 133 of the package connector 134 and a corresponding pad 112 of the printed circuit board 110 when the package 130 is seated on the printed circuit board 110.

FIG. 5 shows a side view of a system having a printed circuit board and an integrated circuit package with a standoff spacer between the printed circuit board and the integrated circuit package. A standoff spacer 140 is between the printed circuit board 110 and the integrated circuit package 130, wherein the bottom 132 of the package 130 is in contact with the standoff spacer 140 and at least three bottom-most points 148 (see FIG. 4A) of the standoff spacer 140 are in contact with the seating surface 114 of the printed circuit board 110. The package 130 has package connectors 134 extending from sides 136 thereof. The printed circuit board 110 has pads 112 flush with the upper surface of printed circuit 110. The shortest distance 146 is the distance between a package connector solder surface 133 of the package connector 134 and a corresponding pad 112. A solder column 120 extends between respective package connector solder surfaces 133 of the package connectors 134 and corresponding pad 112. The height 122 of the solder column 120 is the same length as the shortest distance 146. The package 130 and standoff spacer 140 combined may enforce a shortest distance 146 at least 6 mils (0.152 mm), 8 mils (0.203 mm), or 10 mils (0.254 mm). The solder column 120 may be manually formed between the package connector 134 and a corresponding pad 112, or it may be formed via masking the PCB with a solder stencil. See FIGS. 9A-9D.

The package 130 has a bottom 132 that is raised by a standoff spacer 140 for solder height control, wherein the standoff spacer 140 is attached to the bottom 132. The standoff spacer 140 may be attached to the bottom 132 of the package 130 before seating on a seating surface 114 of a printed circuit board 110 (see FIG. 1). With the standoff spacer 140 attached to the bottom 132 of the package 130, the standoff spacer 140 has a bottom 142 that defines a seating plane 144. The package 130 has package connectors 134 with respective package connector solder surfaces 133, that do not extend through or below the seating plane 144 and are distanced from the seating plane by shortest distance 146. The bottom 142 of the standoff spacer 140 is arranged to make contact with and sit on a printed circuit board when the package connectors 134 are positioned over pads 112 of the printed circuit board 110. (See FIG. 3A). Because the pads 112 on the printed circuit board 110 are flush with the surface on which the package is seated on the printed circuit board 110, the pads 112 are positioned in the seating plane 144 of the package 130 when the package 130 is seated on the printed circuit board 110. To make a connection between a pad 112 and a package connector 134, the solder column height is at least equal to this shortest distance 146 corresponding to a distance between a lower surface of the package connector solder surface 133 of the package connector 134 and a top surface of the pad 112 of the printed circuit board 110 when the package 130 is seated on the printed circuit board 110.

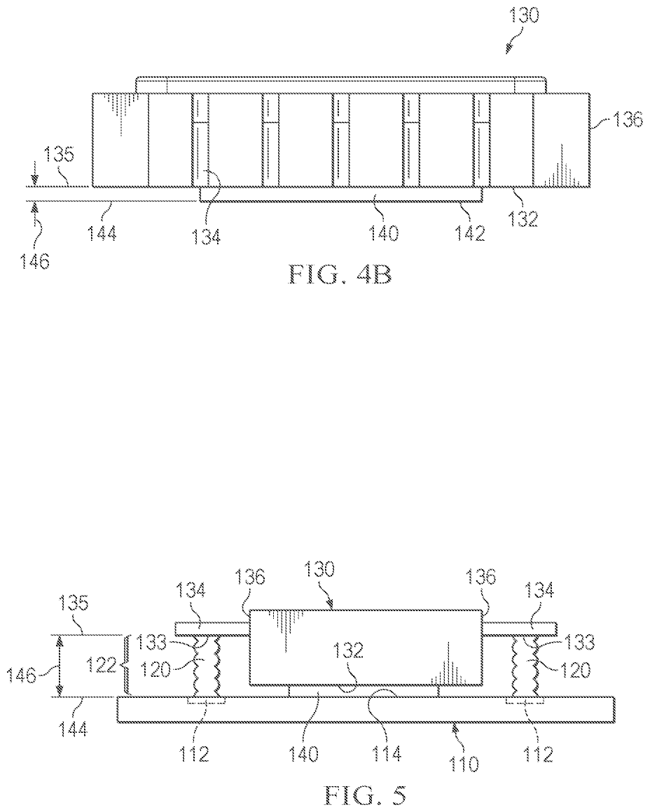

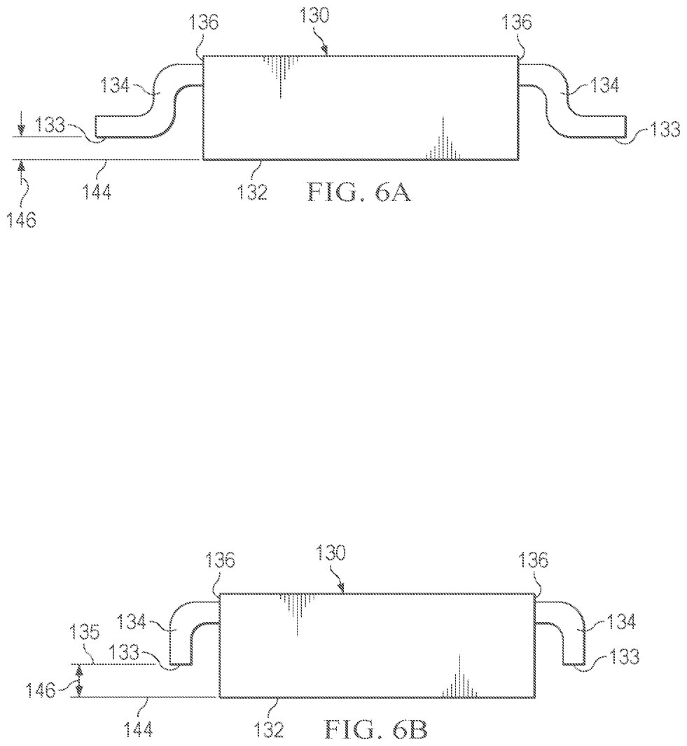

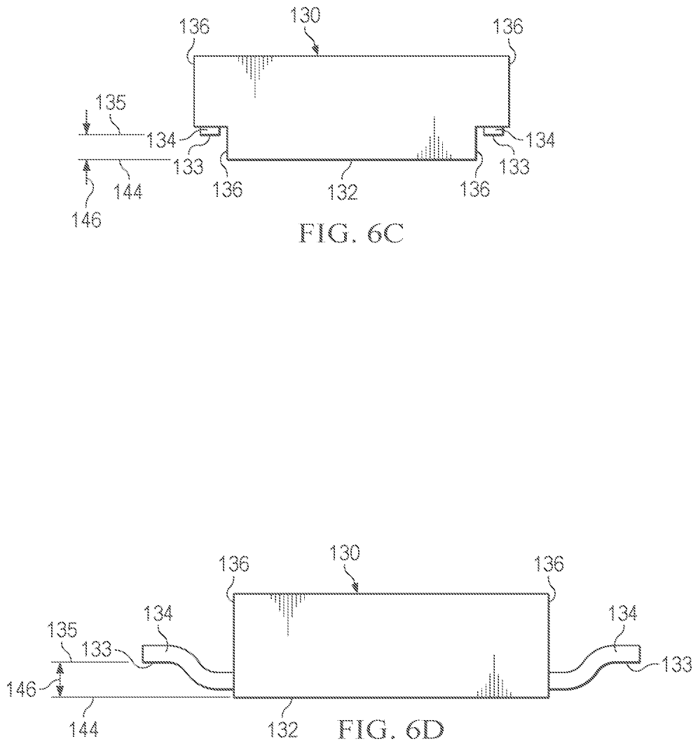

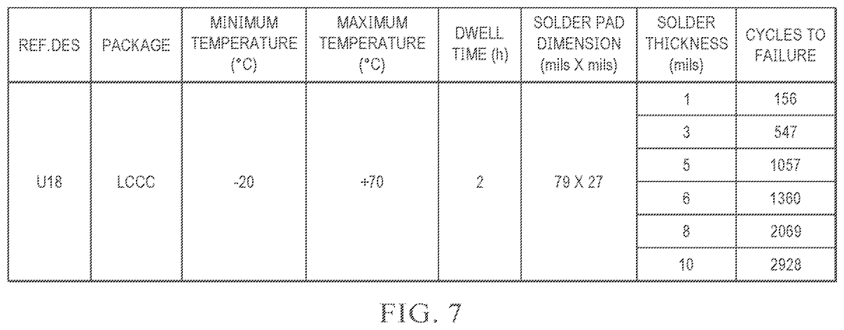

FIG. 6A shows a side view of a package 130 having package connectors 134 extending from the sides 136 of the package. The package 130 may be highly reliable because it may provide thermal fatigue failure resistance by inducing taller solder height. The package 130 has a bottom 132 with at least three bottom-most points that define a seating plane 144. The three bottom-most points could take the shape of a flat surface, two or multiple lines, three or more individual feet, or any locating feature of similar nature. Package connectors 134 extend from the sides 136 and have solder surfaces 133 above the seating plane 144. The shortest distance 146 is a distance between the lowest point of a solder surface 133 of a package connector 134 and the seating plane 144. The package 130 may have a shortest distance 146 at least 6 mils (0.152 mm).

The package 130 provides a surface mount IC package option with package connectors 134 that are higher than the bottom 132 of the package 130, such that respective solder surfaces 133 of package connectors 134 are at a predefined and precisely controlled distance from the seating plane 144. Solder height can be uniformly controlled where the shortest distance 146 provides the dimensional reference as constrained and defined by a surface of contact between the package and the printed circuit board, which may not move/deform during a soldering process (more uniform solder column height may provide quality improvement). When seating the package 130 on a seating surface of the printed circuit board 110, the distance between a lowest solder surface 133 of package connector 134 and a pad 112 on the printed circuit board corresponds to the shortest distance 146. The package 130 is held in a position firmly seated on the printed circuit board to maintain the distance between a package connector 134 and a pad 112 on the printed circuit board 110 during the soldering process. Because the package 130 has a predetermined shortest distance 146 and the package is fully seated during the soldering process, the solder column height may be easily and precisely produced, and is constrained to be at least as tall as the predetermined shortest distance 146. The bottom 132 of the package 130 directly contacting the printed circuit board may also improve thermal cooling for integrated circuits within the package 130. By directly contacting the printed circuit board, vibration modal frequency of the integrated circuit to solder sub-system may be increased.

FIG. 6B shows a side view of a package 130 having package connectors 134, which are pins, extending from the sides 136 of the package. The package 130 may be highly reliable because it may provide thermal fatigue failure resistance by inducing taller solder height. The package 130 has a bottom 132 with at least three bottom-most points 138 (see FIG. 2B) that define a seating plane 144. Package connectors 134 extend from the sides 136 and have solder surfaces 133 above the seating plane 144. The shortest distance 146 is a distance between the lowest point of a solder surface 133 of a package connector 134 and the seating plane 144. The package 130 may have a shortest distance 146 at least 6 mils (0.152 mm), 8 mils (0.203 mm), or 10 mils (0.254 mm).

FIG. 6C shows a side view of a package 130 having package connectors 134, which are pads extending from the sides 136 of the package. The package 130 may be highly reliable because it may provide thermal fatigue failure resistance by inducing taller solder height. The package 130 has a bottom 132 with at least three bottom-most points 138 (see FIG. 2B) that define a seating plane 144. Package connectors 134 extend from the sides 136 and have solder surfaces 133 above the seating plane 144. The shortest distance 146 is a distance between the lowest solder surface 133 of a package connector 134 and the seating plane 144. The package 130 may have a shortest distance 146 at least 6 mils (0.152 mm), 8 mils (0.203 mm), or 10 mils (0.254 mm).

FIG. 6D shows a side view of a package 130 having package connectors 134, which are leads extending from the sides 136 of the package. The package 130 may be highly reliable because it may provide thermal fatigue failure resistance by inducing taller solder height. The package 130 has a bottom 132 with at least three bottom-most points (see FIG. 2B) that define a seating plane 144. Package connectors 134 extend from the sides 136 above the seating plane 144 and have solder surfaces 133 for soldering to solder paste columns. The shortest distance 146 is a distance between the lowest solder surface 133 and the seating plane 144. In one example, the lowest solder surface 133 may define a connecting plane 135 parallel to the seating plane 144 and the shortest distance 146 is the shortest distance between the planes. The package 130 may have a shortest distance 146 at least 6 mils (0.152 mm), 8 mils (0.203 mm), or 10 mils (0.254 mm).

Aspects may improve vibrational and shock performance. In addition, by sharing load via contacts made between a bottom 132 and the seating plane 144, vibrational stresses taken by integrated circuit pins and solder may be reduced (improved vibrational and shock fatigue lives of electronics).

Aspects may provide an economical and easy method of improving thermal lives for electronics, quality improvement and potential cost saving, by removing additional design measures.

Aspects provide a packaging option with a controlled height of package connectors relative to the bottom of the integrated circuit package. A structural feature may be added to the bottom of any integrated circuit chip packaging, as an integral part of the package so that the integrated circuit pins can be raised from a seating plane, with pin height precisely and evenly controlled, when there is no empty space between the package and its mounting location on the printed circuit board.

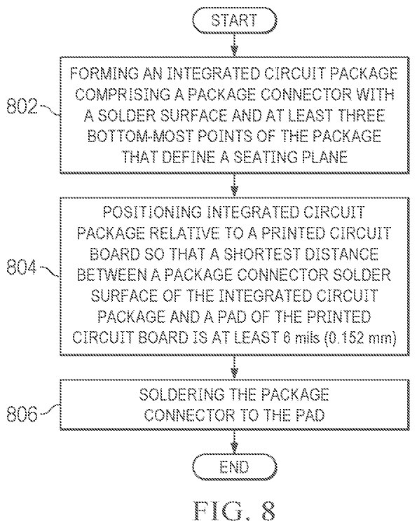

FIG. 7 shows a table of data for a solder thermal fatigue life for different solder column heights. Leadless chip carrier (LCCC) packages having different solder heights were cycled between −20 degrees C. and 70 degrees C. over two hours. A package connected to a printed circuit board with a solder height of 6 mils (0.152 mm) endured 129% more cycles to failure than a traditional solder height of 5 mils (0.127 mm). A package connected to a printed circuit board with a solder height of 8 mils (0.203 mm) endured 196% more cycles to failure than a traditional solder height of 5 mils (0.127 mm). A package connected to a printed circuit board with a solder height of 10 mils (0.254 mm) endured 277% more cycles to failure than a traditional solder height of 5 mils (0.127 mm).

Methods to precisely increase and control the solder column height under integrated circuit packages may improve the thermal cycle fatigue life and quality consistency for final products. Methods include: controlling solder thickness on PCB boards; modifying integrated circuit packages to position package connectors at a predefined positive shortest distance from a seating surface. Control of a solder thickness may be accomplished by adjusting manufacturing procedure such as solder paste stencil thickness.

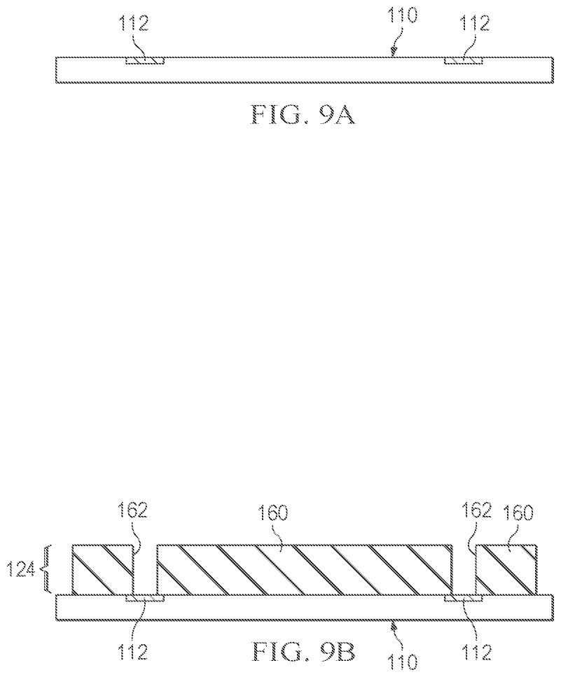

FIG. 8 shows a method of controlling solder column height. An integrated circuit package is formed 802 comprising a package connector with a solder surface and at least three bottom-most points of the package that define a seating plane. The integrated circuit package is positioned 804 relative to a printed circuit board so that a shortest distance between a package connector solder surface of the integrated circuit package and a pad of the printed circuit board is at least 6 mils (0.152 mm). The package connector is soldered 806 to the pad.

FIGS. 9A-9D show cross-sectional, side views of a printed circuit board at sequential steps of a solder column forming process. FIG. 9A shows a printed circuit board 110 with pads 112. FIG. 9B shows the printed circuit board 110 with a solder paste stencil 160 positioned thereon, wherein patterned holes 162 in the solder paste stencil 160 are positioned at the pads 112. The solder paste stencil 160 has a thickness 124. FIG. 9C shows the printed circuit board 110 with the solder paste stencil 160, wherein solder paste 166 is being applied to the solder paste stencil 160 with a wiper blade 164 so that the solder paste 166 is pushed into the patterned holes 162 and into contact with the pads 112. FIG. 9D shows the printed circuit board 110 with the solder paste stencil 160 removed to leave solder columns 120 on the pads 112, and a package 130 is positioned on the printed circuit board 110 with its package connectors 134 on the solder columns 120. The thickness 124 of the solder paste stencil 160, together with the package connectors 134, may define the height 122 of the solder columns 120. The thickness 124 of the solder paste stencil 160 may be 6 mils (0.152 mm), 8 mils (0.203 mm), or 10 mils (0.254 mm), or at any higher values. Masking the printed circuit board 110 with the solder paste stencil 160 having a thickness of at least 6 mils (0.152 mm) may facilitate positioning the integrated circuit package 130 relative to the printed circuit board 110 so that the shortest distance 146 (see FIG. 3) between a package connector 134 and the pad 112 is at least 6 mils (0.152 mm). In different aspects, the package 130 may and may not be in contact with the printed circuit board 110 when the package connectors 134 are on the solder columns 120.

Aspects provided may be applicable in any industries or applications where electronic life and reliability is an issue: electric vehicles, locomotives, aerospace, or anywhere that the integrated circuit itself or environmental temperature fluctuation is high.

Although examples have been described above, other variations and examples may be made from this disclosure without departing from the spirit and scope of these disclosed examples.

1. A device comprising:
an integrated circuit package comprising a package connector with a solder surface and at least three bottom-most points of the package that define a seating plane, wherein the shortest distance between the seating plane and the package connector solder surface is at least 6 mils (0.152 mm).

2. The device as in claim 1, wherein the shortest distance between the seating plane and the package connector solder surface is at least 8 mils (0.203 mm).

3. The device as in claim 1, wherein the shortest distance between the seating plane and the package connector solder surface is at least 10 mils (0.254 mm).

4. The device as in claim 1, wherein the package connector is selected from a pin, a lead, and a pad.

5. The device as in claim 1, comprising a standoff spacer attached to the integrated circuit package and comprising at least three bottom-most points that define a seating plane.

6. A system comprising:
a printed circuit board comprising a pad;
an integrated circuit package comprising a package connector and at least three bottom-most points of the package in contact with the printed circuit board; and
a solder column having a height at least 6 mils (0.152 mm) electrically and mechanically connecting the pad to the package connector.

7. The system as in claim 6, wherein the height of the solder column is at least 8 mils (0.203 mm).

8. The system as in claim 6, wherein the height of the solder column is at least 10 mils (0.254 mm).

9. The system as in claim 6, wherein the package connector is selected from a pin, a lead, and a pad.

10. The system as in claim 6, comprising a standoff spacer between the printed circuit board and the integrated circuit package, wherein the at least three bottom-most points of the package are in contact with the standoff spacer and the standoff spacer is in contact with the printed circuit board.

11. The system as in claim 10, wherein the standoff spacer is in contact with both the printed circuit board and the integrated circuit package and has a thickness sufficient to ensure a shortest distance between the package connector and the pad is at least 6 mils (0.152 mm).

12. The system as in claim 10, wherein the integrated circuit package has a bottom plane defined by at least three bottom-most points of the package, wherein a shortest distance between the bottom plane and the package connector is at least 6 mils (0.152 mm).

13. A method comprising:
forming an integrated circuit package comprising a package connector with a solder surface and at least three bottom-most points of the package that define a seating plane;
positioning the integrated circuit package relative to a printed circuit board so that a shortest distance between a package connector solder surface of the integrated circuit package and a pad of the printed circuit board is at least 6 mils (0.152 mm); and
soldering the package connector to the pad.

14. The method as in claim 13, comprises masking the printed circuit board with a solder paste stencil having a thickness of at least 6 mils (0.152 mm).

15. The method as in claim 14, wherein the thickness of the solder paste stencil facilitates a solder column having a height to span the shortest distance between a package connector solder surface of the integrated circuit package and a pad of the printed circuit board.

16. The method as in claim 13, comprising positioning a standoff spacer between the integrated circuit package and the printed circuit board.

17. The method as in claim 13, wherein the shortest distance between the package connector solder surface and the pad is at least 8 mils (0.203 mm).

18. The method as in claim 13, wherein the shortest distance between the package connector solder surface and the pad is at least 10 mils (0.254 mm).

19. The method as in claim 13, wherein the shortest distance between the seating plane and the package connector solder surface is at least 6 mils (0.152 mm).

20. The method as in claim 13, wherein soldering the package connector to the pad comprises forming a solder column having a height of at least 6 mils (0.152 mm) electrically and mechanically connecting the pad to the package connector solder surface.
